(19) United States
(12) Patent Application Publication
(10) Pub. No.: US 2026/0314773 A1
(43) Pub. Date: Oct. 15, 2026

(54) Portable Electronic Device Case Stand Modular System

(71) Applicant: Pioneer Square Brands, Inc., High Point, NC (US)

(72) Inventors: Soren Sibbesen, Jamestown, NC (US); Brian Lewis Piper, Seattle, WA (US); Quentin Wade Forbes, Winston Salem, NC (US); Richard Kennedy, Antioch, TN (US)

(73) Assignee: Pioneer Square Brands, Inc., High Point, NC (US)

(21) Appl. No.: 19/424,181

(22) Filed: Dec. 18, 2025

Related U.S. Application Data
(60) Provisional application No. 63/789,384, filed on Apr. 15, 2025.

(51) Int. Cl. A45C 11/00; A45C 13/04

(52) U.S. Cl. CPC A45C 11/003; A45C 13/04; A45C 2200/10

(57) ABSTRACT

A case system for a portable electronic device includes a back member, a frame member, and a transparent sheet. The back member includes an interior surface portion, an exterior surface portion, and at least one side portion having at least one outwardly extending rib portion. The frame member includes a central opening with a periphery, a perimeter body portion peripherally bounding at least a portion of the periphery, and at least one groove portion facing the central opening for coupling with the rib portion of the back member. At least one ledge portion extends inwardly from the perimeter body portion to support the transparent sheet positioned adjacent thereto. When assembled, the back member and frame member securely enclose the portable electronic device with the transparent sheet aligned with a device display surface. Other aspects are described in the claims, drawings, and text forming a part of the present disclosure.

In one or more aspects a case system for a portable electronic device includes (I) a back member including (A) an exterior surface portion, (B) an interior surface portion, and (C) at least one side portion including at least one rib portion extending outwardly; (II) a frame member including (A) a central opening having a periphery, (B) at least one perimeter body portion peripherally bounding at least a portion of the periphery of the central opening and including at least one groove portion facing the central opening, wherein the at least one groove portion is coupled with the at least one rib portion of the back member, (C) at least one ledge portion extending inwardly from the at least one perimeter body portion into the central opening; and (III) at least one transparent sheet portion positioned adjacent to the at least one ledge portion, wherein the interior surface portion of the back member is positioned adjacent to the portable electronic device when the case system is coupled with the portable electronic device.

In implementations wherein the at least one rib portion is continuously extending along at least two side portions of the back member.

In implementations wherein the at least one groove portion forms a continuous groove along the periphery of the central opening.

In implementations wherein the at least one transparent sheet portion is removably retained on the at least one ledge portion.

In implementations wherein the back member is substantially rectangular in shape.

In implementations wherein the back member includes at least one polycarbonate material, and the frame member includes at least one thermoplastic polyurethane material.

In implementations wherein the at least one ledge portion includes at least one support surface for contacting the at least one transparent sheet portion.

In one or more aspects a case system for a portable electronic device including (I) a back member including (A) an interior surface portion, and (B) at least one side portion; (II) a frame member including (A) a central opening with a periphery sized to receive the portable electronic device when the case system is coupled with the portable electronic device, (B) at least one perimeter body portion peripherally bounding at least a portion of the periphery of the central opening, wherein the at least one perimeter body portion of the frame member is couplable with the at least one side portion of the back member; and (III) a transparent sheet sized to cover the central opening of the frame member when positioned adjacent the at least one perimeter body portion of the frame member.

In implementations wherein the frame member further includes a circumferential groove defined as a continuous channel within inner surfaces of the at least one perimeter body portion.

Implementations include at least one rib portion extending from the back member, wherein the back member includes four sides and the at least one rib portion extends continuously along three or more sides.

In implementations the frame member further includes at least one ledge portion, and wherein the transparent sheet is planar and lies in contact with an inward-facing surface of the at least one ledge portion.

Implementations include at least one rib portion and a circumferential groove, wherein the frame member is flexibly deformable to allow the at least one rib portion to snap into the circumferential groove.

In implementations the transparent sheet and the back member are both removably attachable to the frame member.

In implementations the portable electronic device includes a rear surface portion that contacts the interior surface portion of the back member when the portable electronic device is coupled with the case system.

In one or more aspects a case system for a portable electronic device including (I) a back member including (A) a plurality of side portions; and (II) a frame member including (A) a central opening with a periphery, and (B) a plurality of perimeter body portions bounding at least a portion of the periphery of the central opening, wherein the plurality of side portions of the back member are respectively couplable with the plurality of perimeter body portions of the frame member to secure the back member to the frame member when the case system is coupled with a portable electronic device.

In implementations the interior surface portion of the back member is adjacent to the portable electronic device when the portable electronic device is coupled with the case system.

In implementations the back member includes a plurality of rib portions respectively extending from the plurality of side portions of the back member, and the plurality of perimeter body portions of the frame member respectively include a plurality of groove portions respectively couplable with the plurality of rib portions.

In implementations the plurality of groove portions respectively extend continuously along corresponding sides of the frame member.

In implementations the plurality of rib portions of the back member are respectively couplable with the plurality of groove portions of the frame member.

Implementations include a transparent sheet, wherein the frame member includes a plurality of ledge portions extending respectively from the plurality of perimeter body portions, and wherein a plurality of portions of the transparent sheet are respectively adjacent to the plurality of ledge portions when the portable electronic device is coupled with the case system.

In addition to the foregoing, other aspects are described in the claims, drawings, and text forming a part of the disclosure set forth herein. Various other aspects are set forth and described in the teachings such as text (e.g., claims and/or detailed description) and/or drawings of the present disclosure. The foregoing is a summary and thus may contain simplifications, generalizations, inclusions, or omissions of detail; consequently, those skilled in the art will appreciate that the summary is illustrative only and is NOT intended to be in any way limiting. Other aspects, features, and advantages of the devices and/or processes and/or other subject matter described herein will become apparent in the teachings set forth herein.

### BRIEF DESCRIPTION OF THE FIGURES

For a more complete understanding of implementations, reference now is made to the following descriptions taken in connection with the accompanying drawings. The use of the same symbols in different drawings typically indicates similar or identical items, unless context dictates otherwise.

With reference now to the figures, shown are one or more examples of Portable Electronic Device Case Modular System, articles of manufacture, compositions of matter for same that may provide context, for instance, in introducing one or more processes and/or devices described herein.

### FIGURE DESCRIPTIONS FOR PRESENT APPLICATION

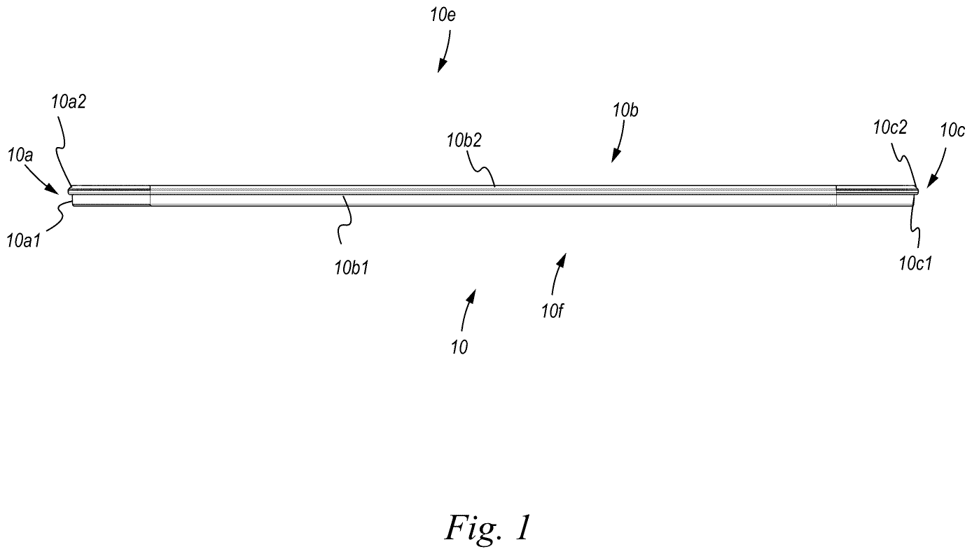

FIG. 1 is a right side elevational view of a back member.

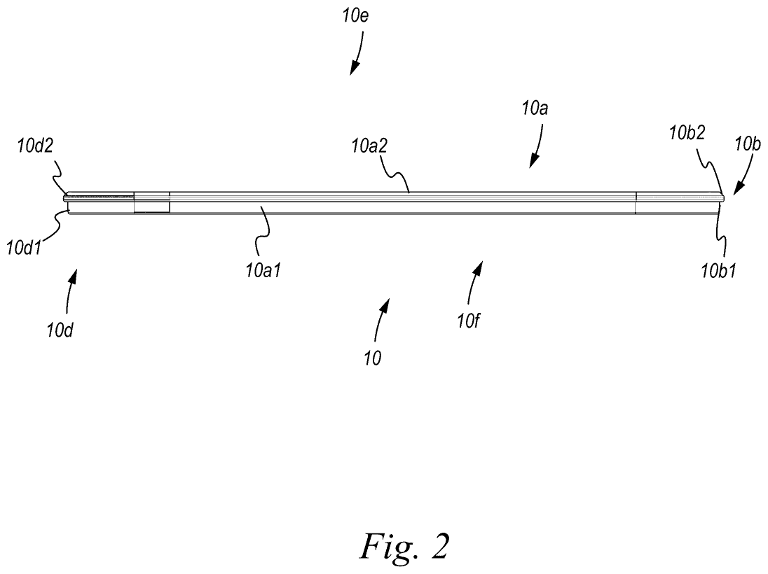

FIG. 2 is a top plan view of the back member of FIG. 1.

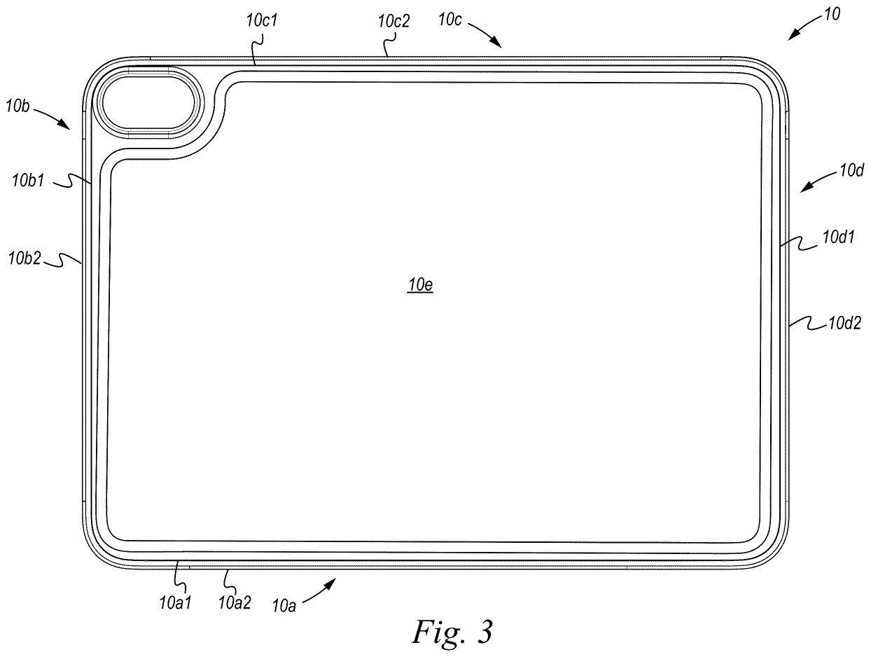

FIG. 3 is a front elevational view of the back member of FIG. 1.

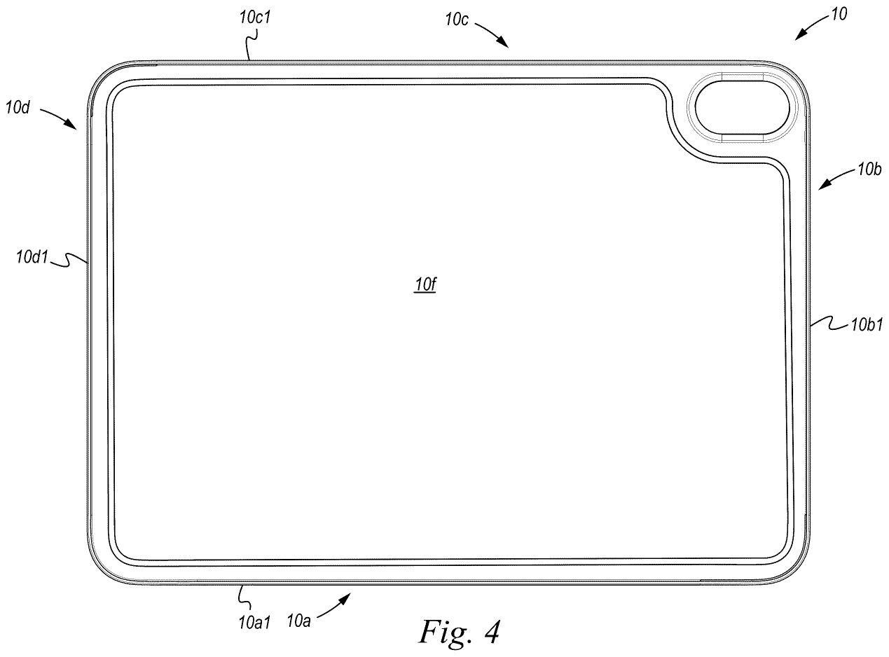

FIG. 4 is a rear elevational view of the back member of FIG. 1.

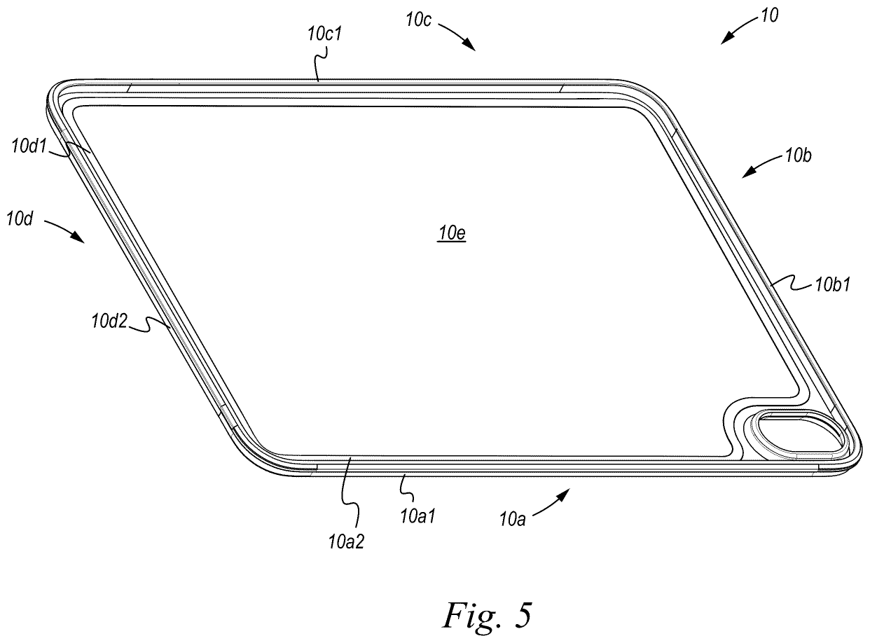

FIG. 5 is a front-left-top isometric view of the back member of FIG. 1.

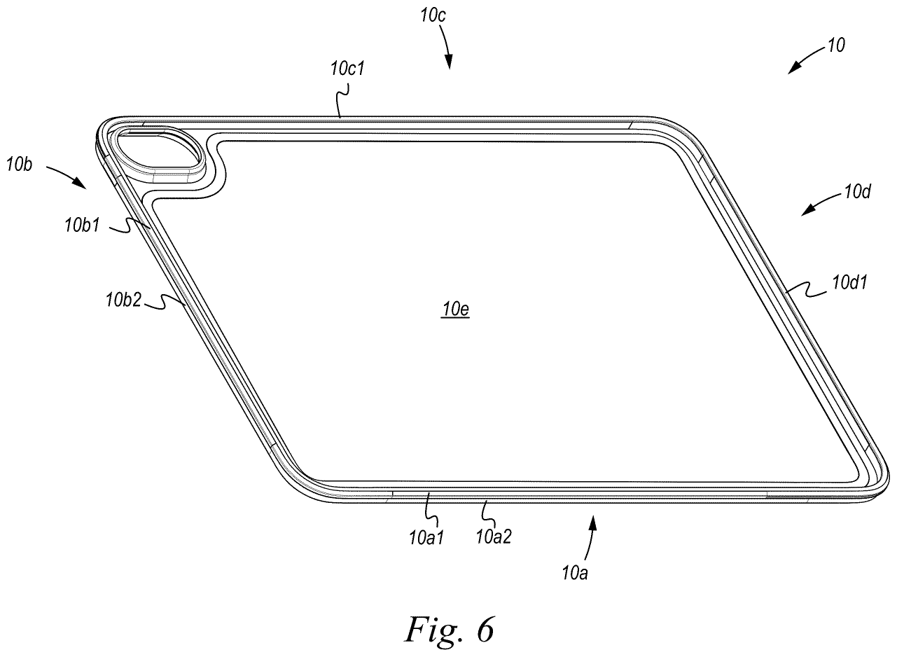

FIG. 6 is a front-right-top isometric view of the back member of FIG. 1.

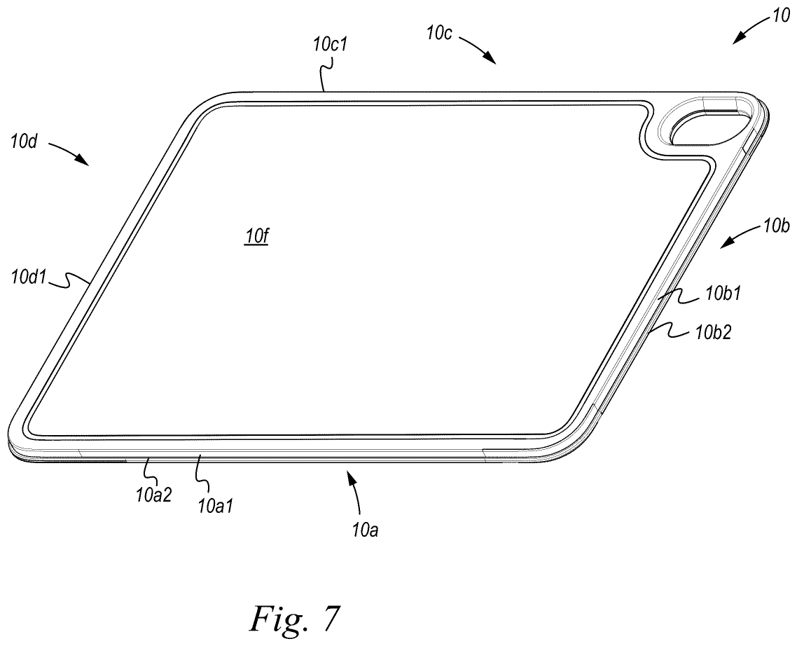

FIG. 7 is a back-left-top isometric view of the back member of FIG. 1.

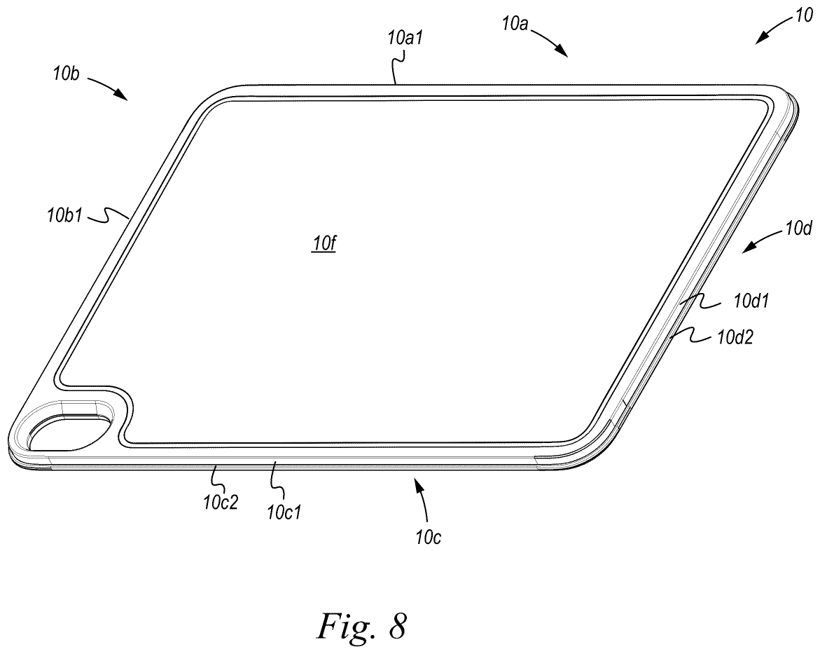

FIG. 8 is a back-right-bottom isometric view of the back member of FIG. 1.

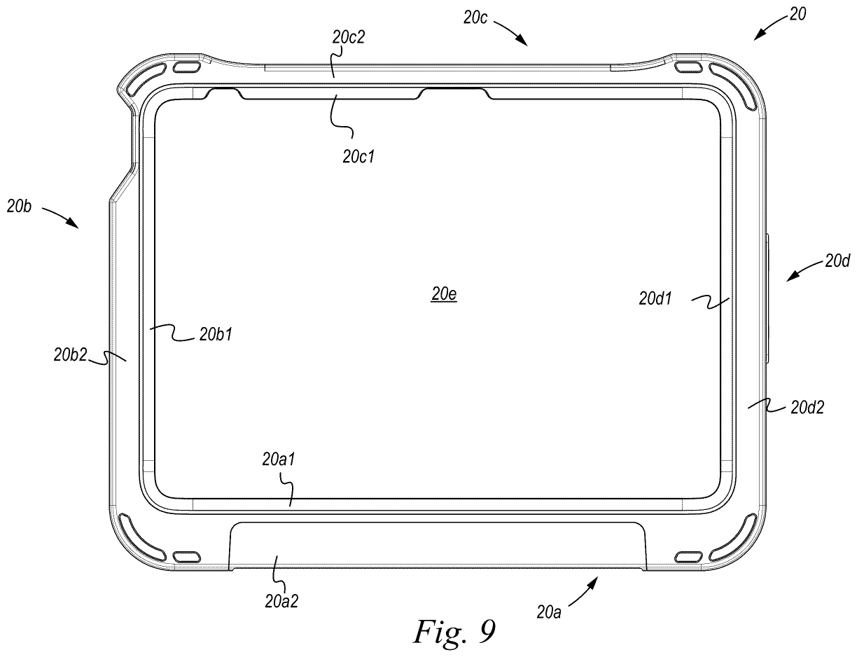

FIG. 9 is a front elevational view of a frame member.

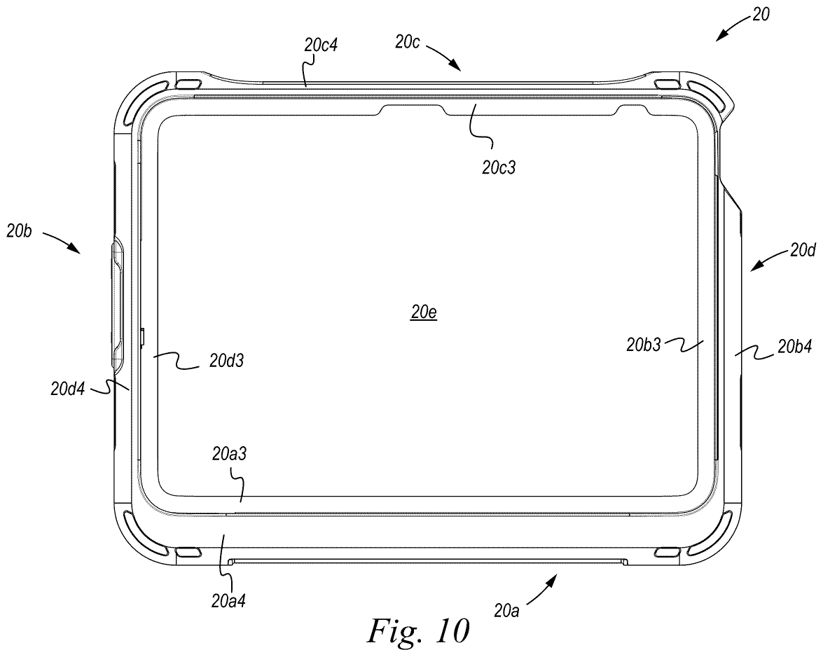

FIG. 10 is a rear elevational view of the frame member of FIG. 9.

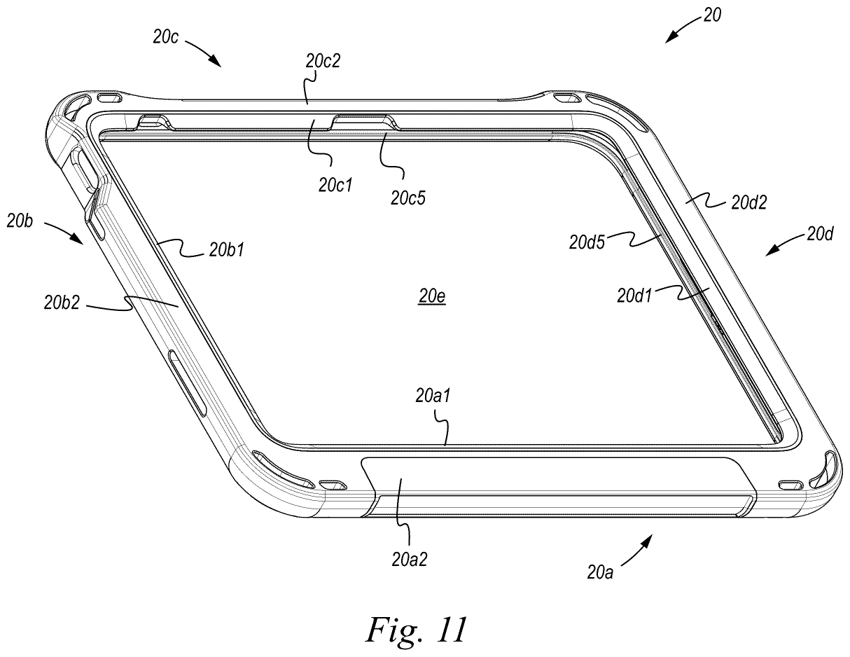

FIG. 11 is a front-right-top isometric view of the frame member of FIG. 9.

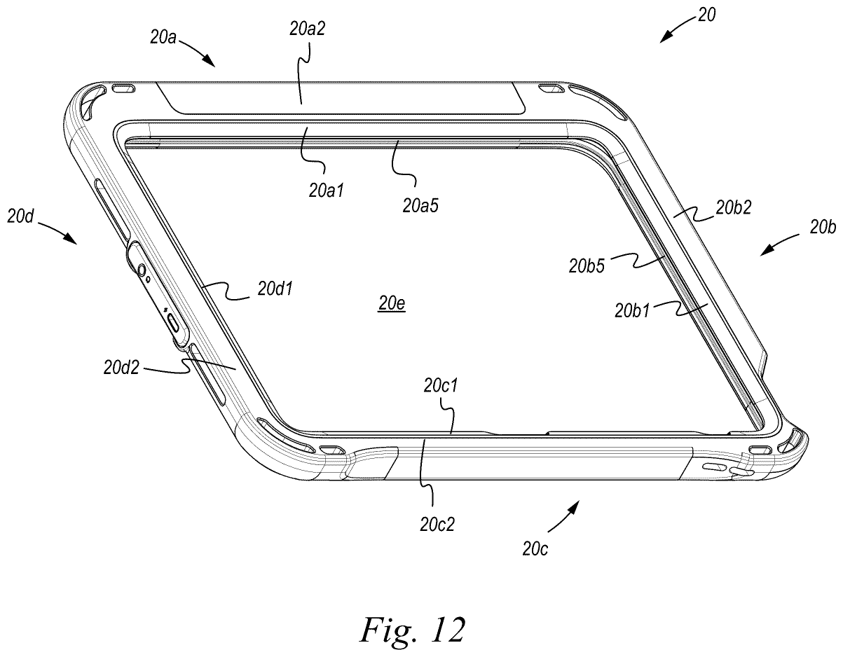

FIG. 12 is a front-left-top isometric view of the frame member of FIG. 9.

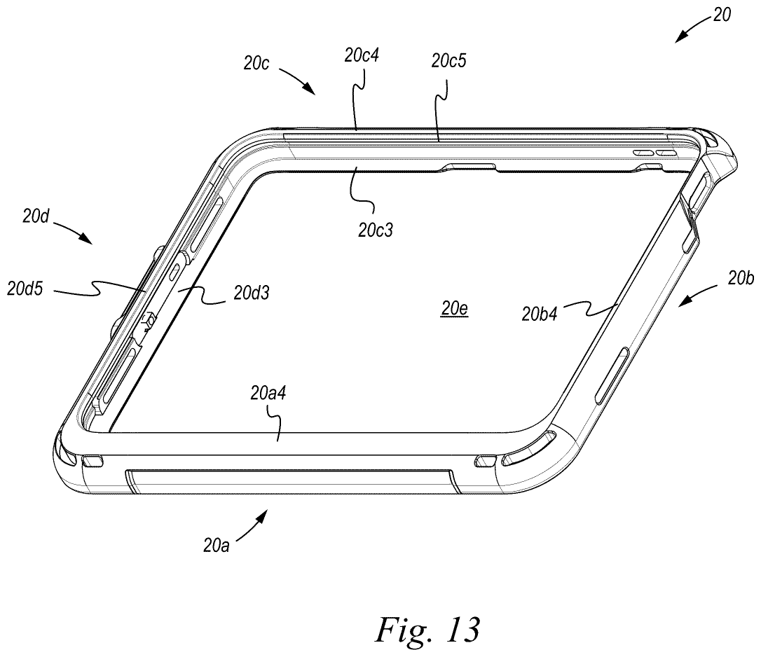

FIG. 13 is a back-left-top isometric view of the frame member of FIG. 9.

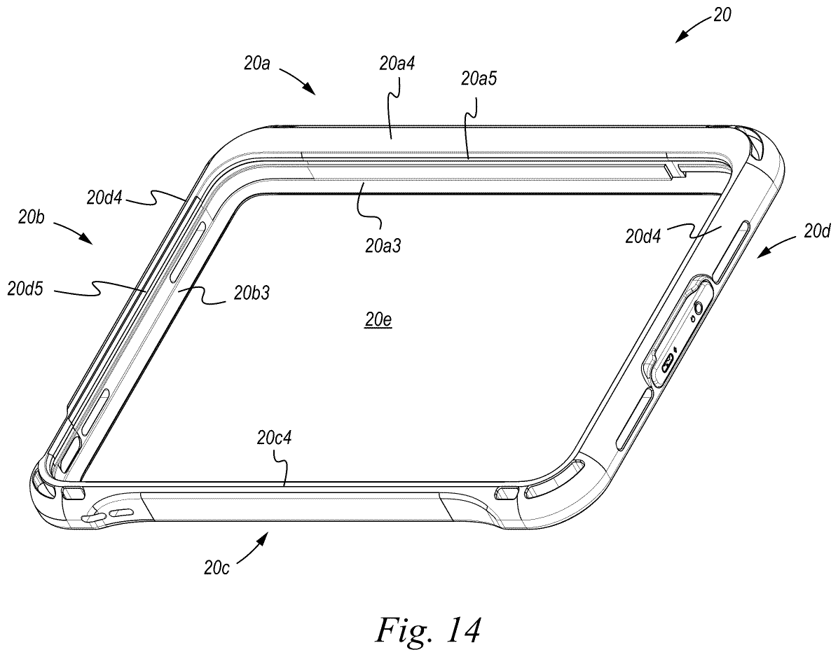

FIG. 14 is a front-right-bottom isometric view of the frame member of FIG. 9.

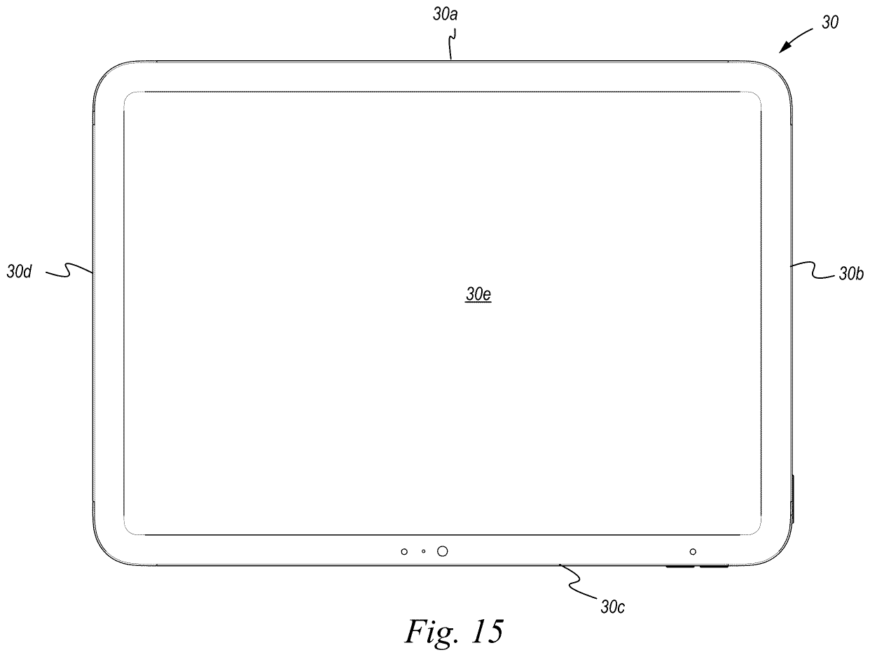

FIG. 15 is a front elevational view of a portable electronic device.

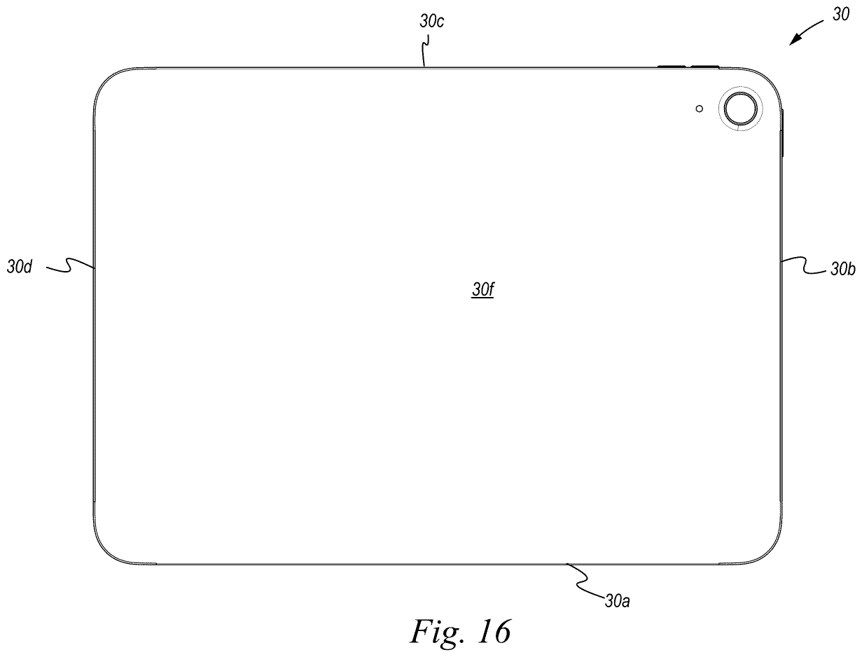

FIG. 16 is a rear elevational view of the portable electronic device of FIG. 15.

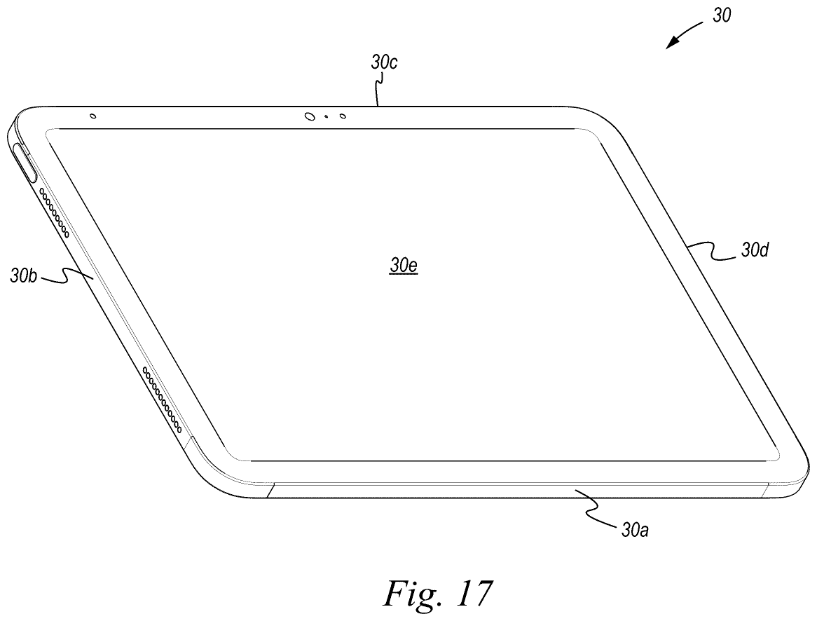

FIG. 17 is a front-right-top isometric view of the portable electronic device of FIG. 15.

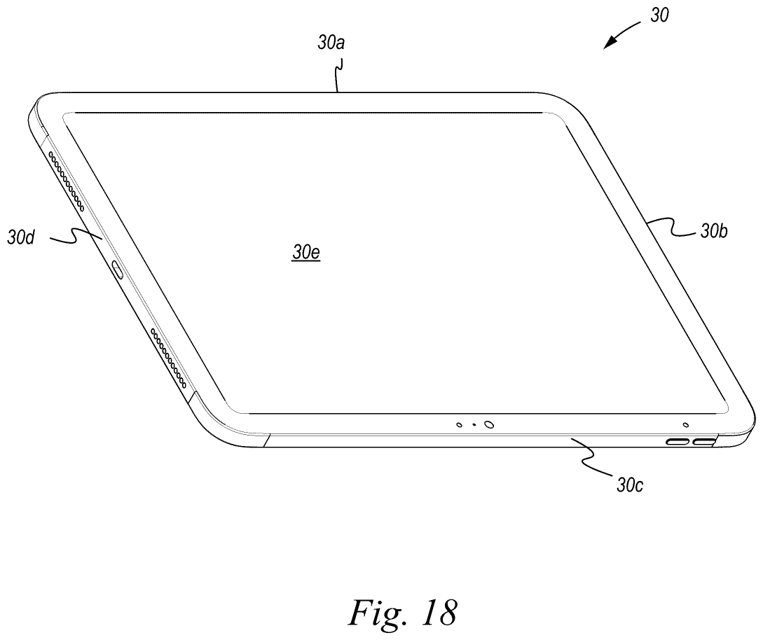

FIG. 18 is a front-left-top isometric view of the portable electronic device of FIG. 15.

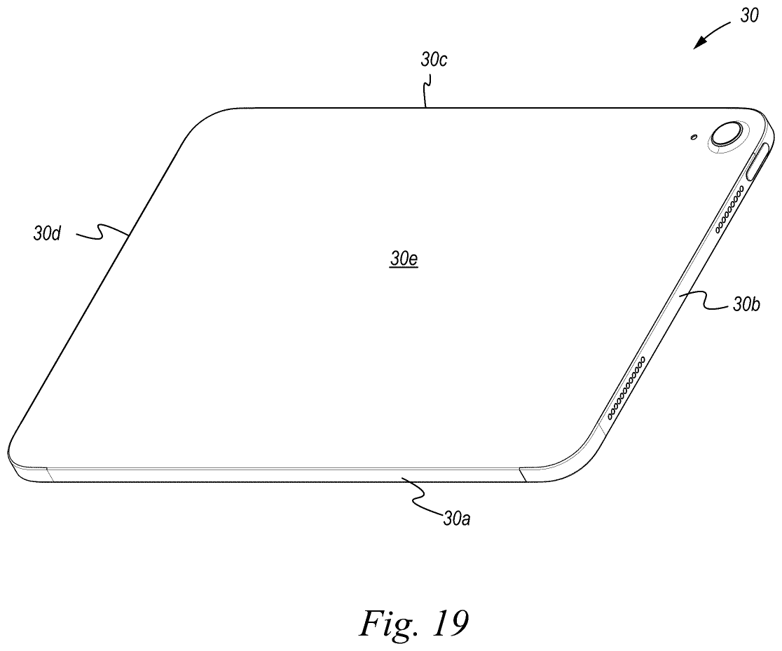

FIG. 19 is a back-left-top isometric view of the portable electronic device of FIG. 15.

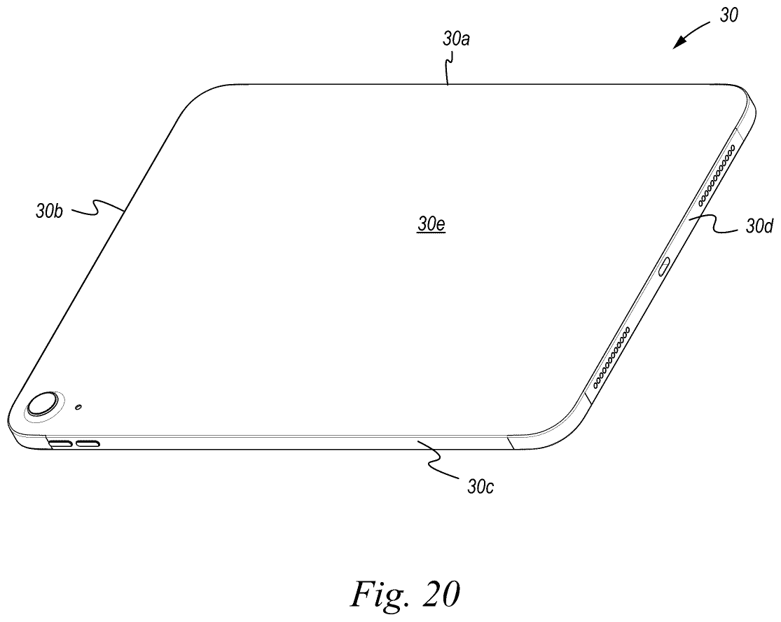

FIG. 20 is a front-right-bottom isometric view of the portable electronic device of FIG. 15.

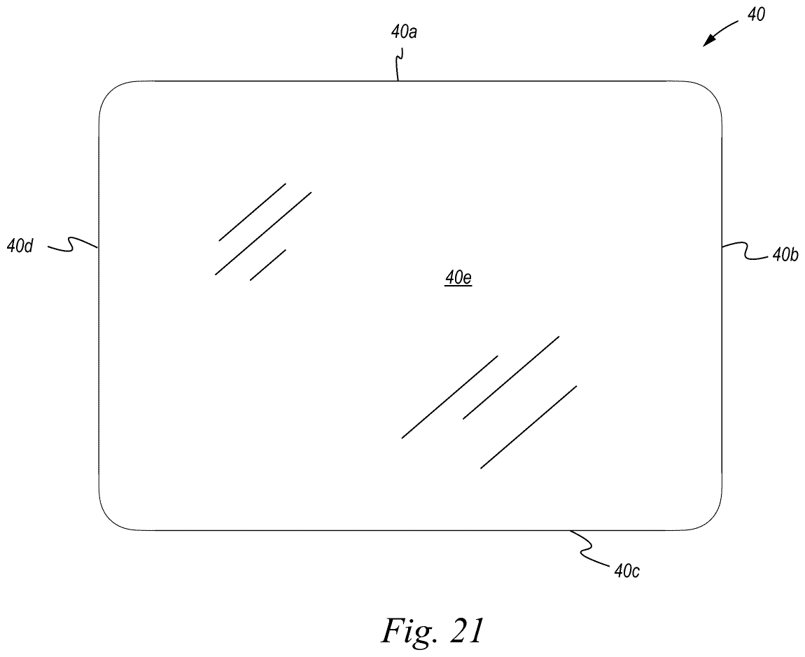

FIG. 21 is a front elevational view of a sheet member.

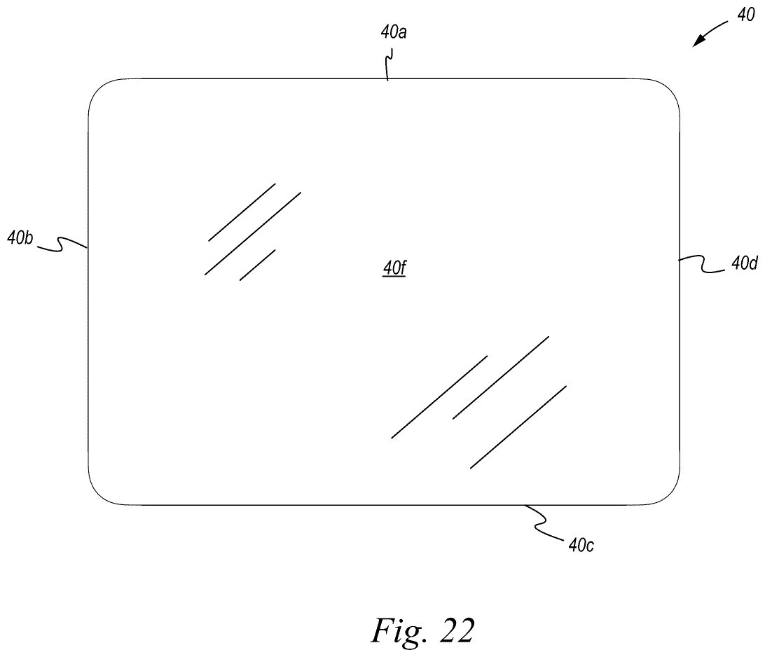

FIG. 22 is a rear elevational view of the sheet member of FIG. 21.

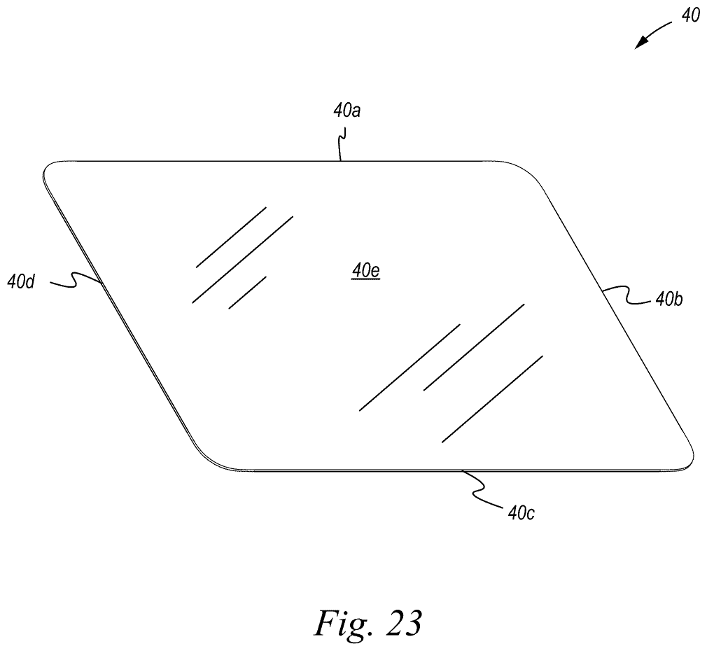

FIG. 23 is a back-right-top isometric view of the sheet member of FIG. 21.

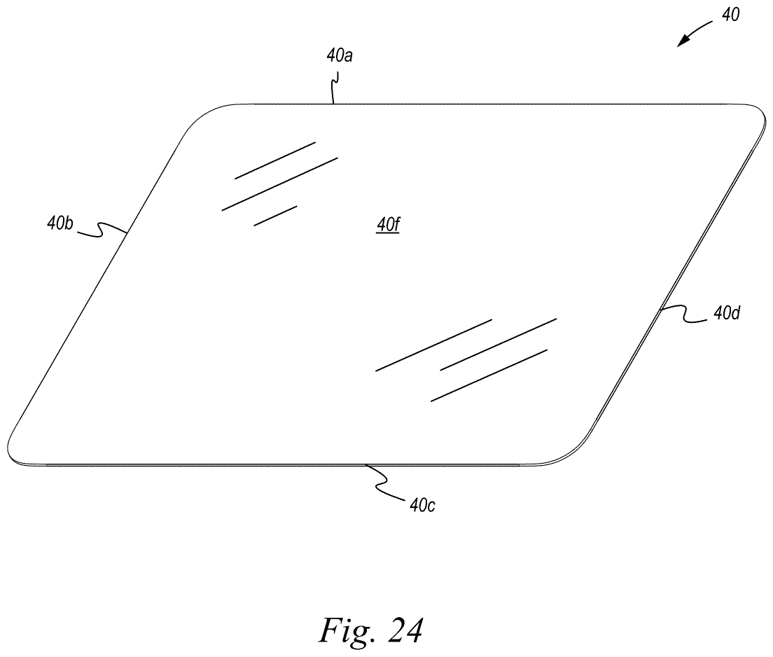

FIG. 24 is a back-left-top isometric view of the sheet member of FIG. 21.

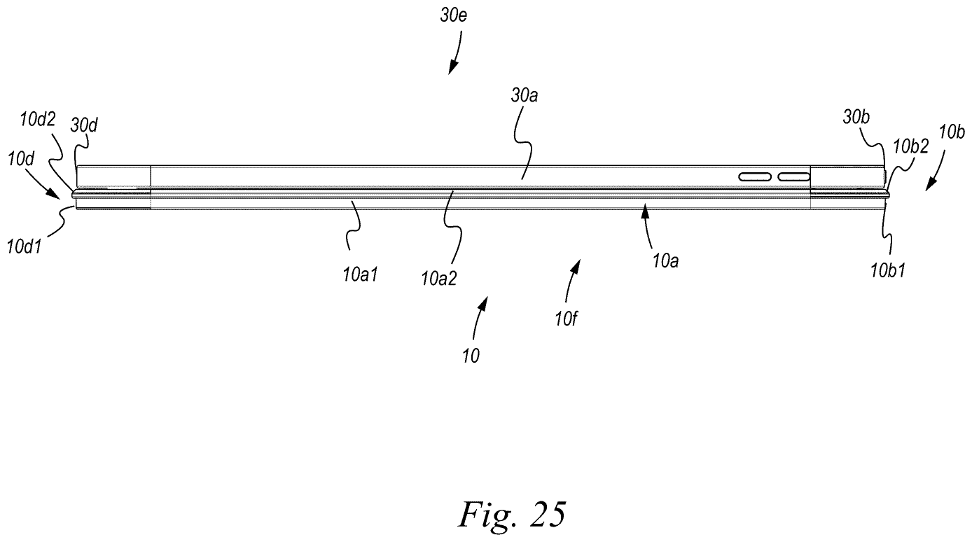

FIG. 25 is a right side elevational view of the back member of FIG. 1 coupled with the portable electronic device of FIG. 15.

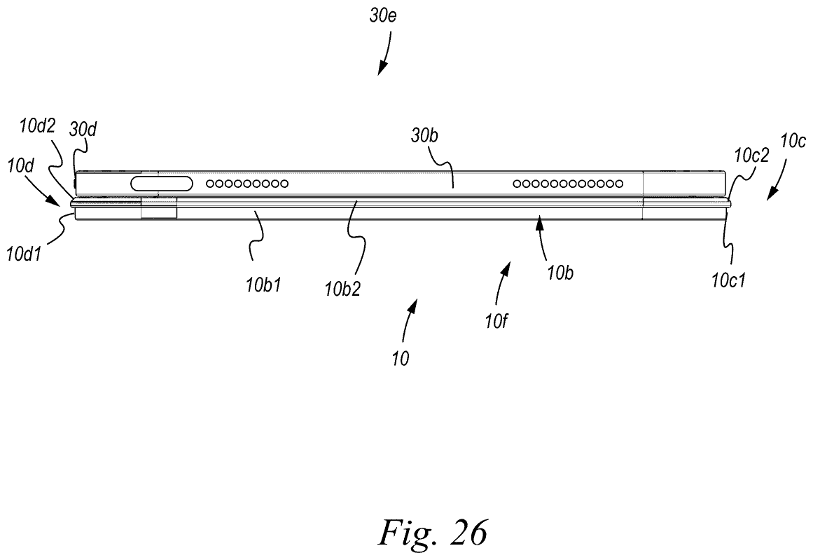

FIG. 26 is a top plan view of the back member of FIG. 1 coupled with the portable electronic device of FIG. 15.

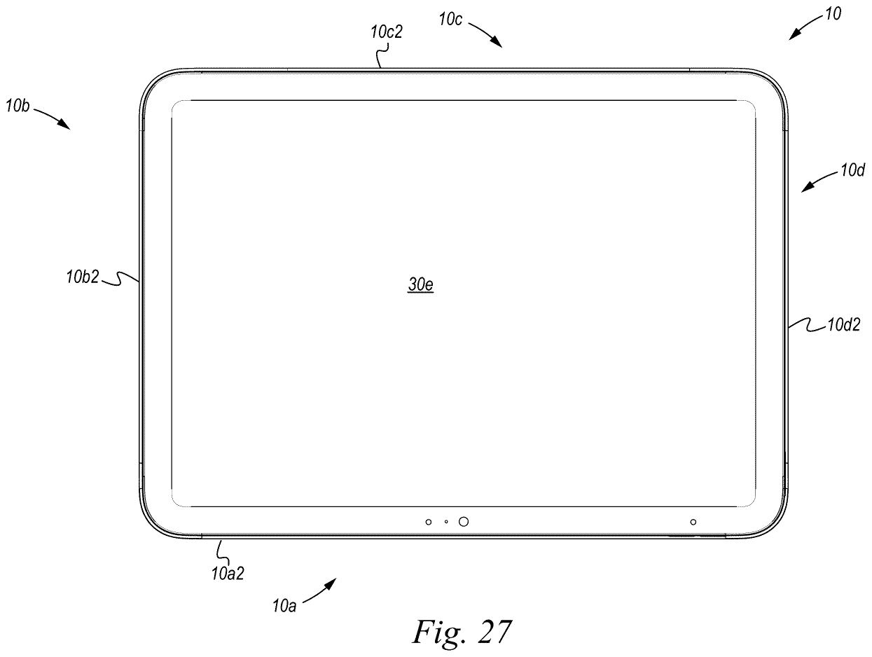

FIG. 27 is a front elevational view of the back member of FIG. 1 coupled with the portable electronic device of FIG. 15.

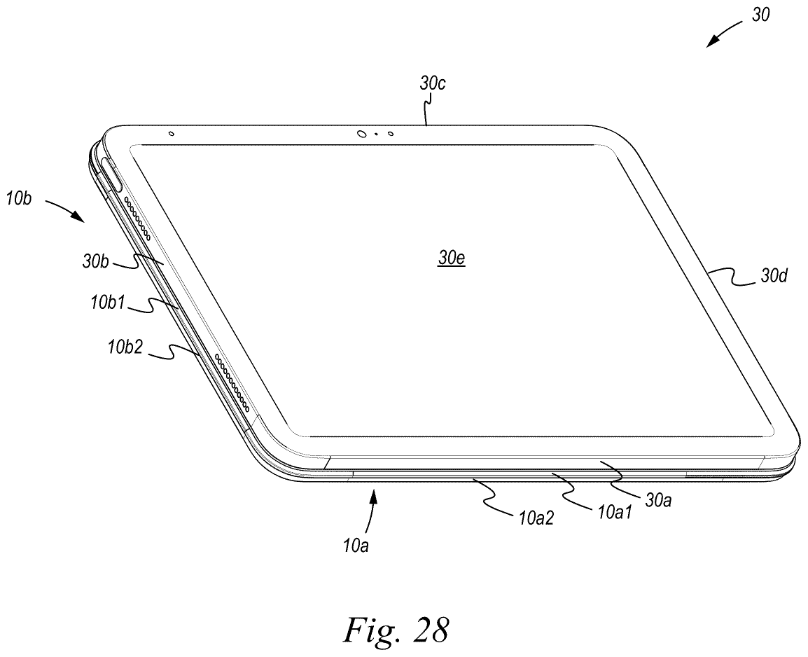

FIG. 28 is a back-right-top isometric view of the back member of FIG. 1 coupled with the portable electronic device of FIG. 15.

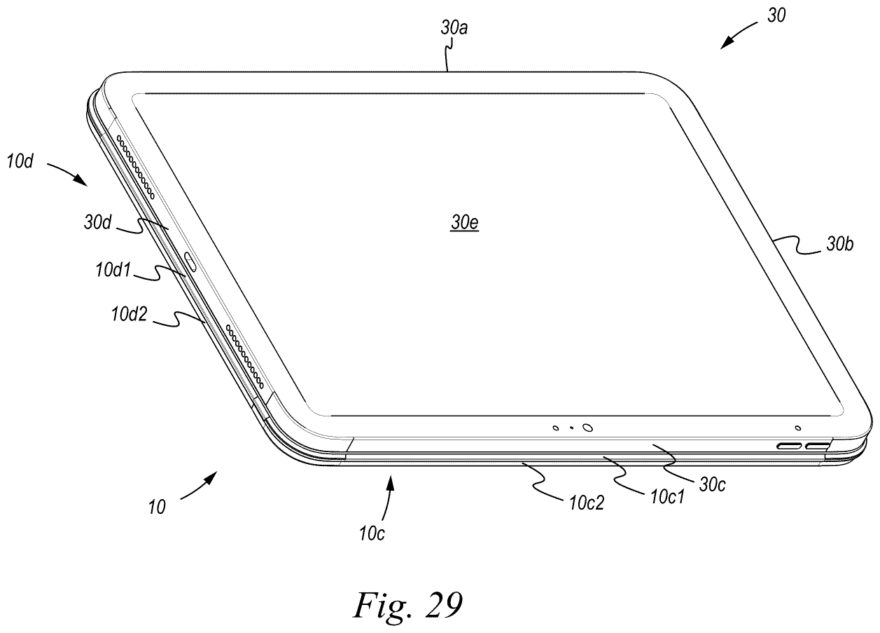

FIG. 29 is a front-left-top isometric view of the back member of FIG. 1 coupled with the portable electronic device of FIG. 15.

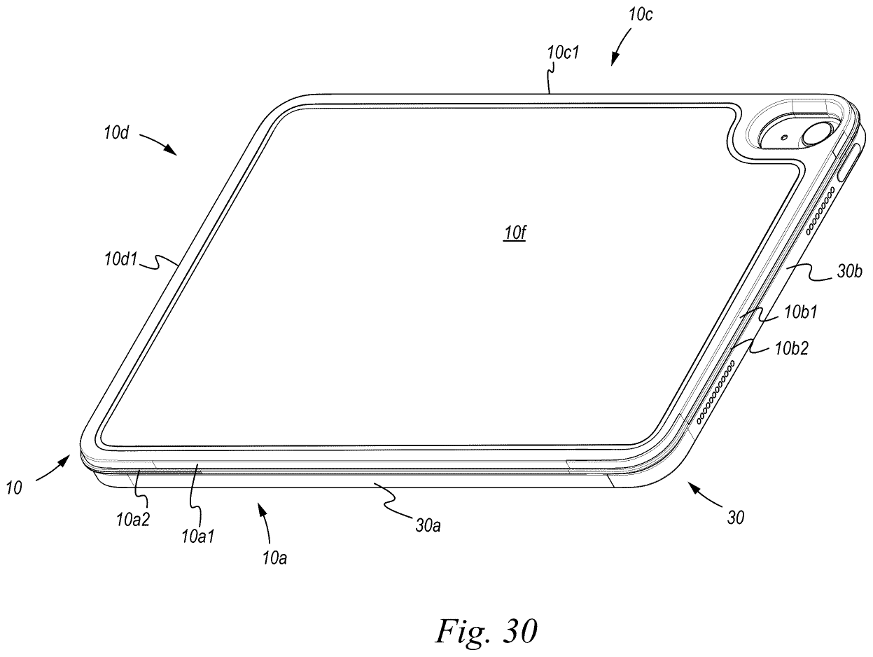

FIG. 30 is a back-left-top isometric view of the back member of FIG. 1 coupled with the portable electronic device of FIG. 15.

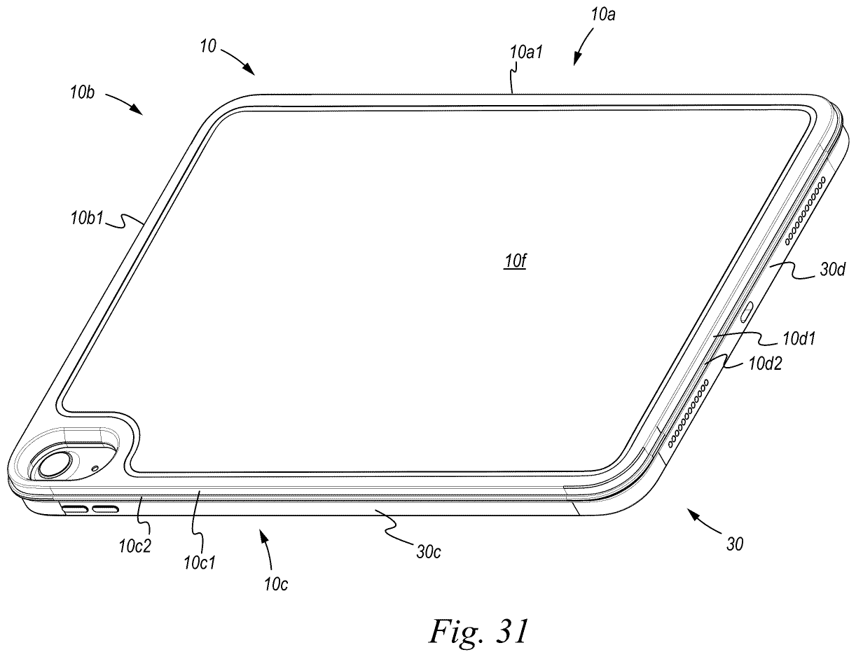

FIG. 31 is a front-right-bottom isometric view of the back member of FIG. 1 coupled with the portable electronic device of FIG. 15.

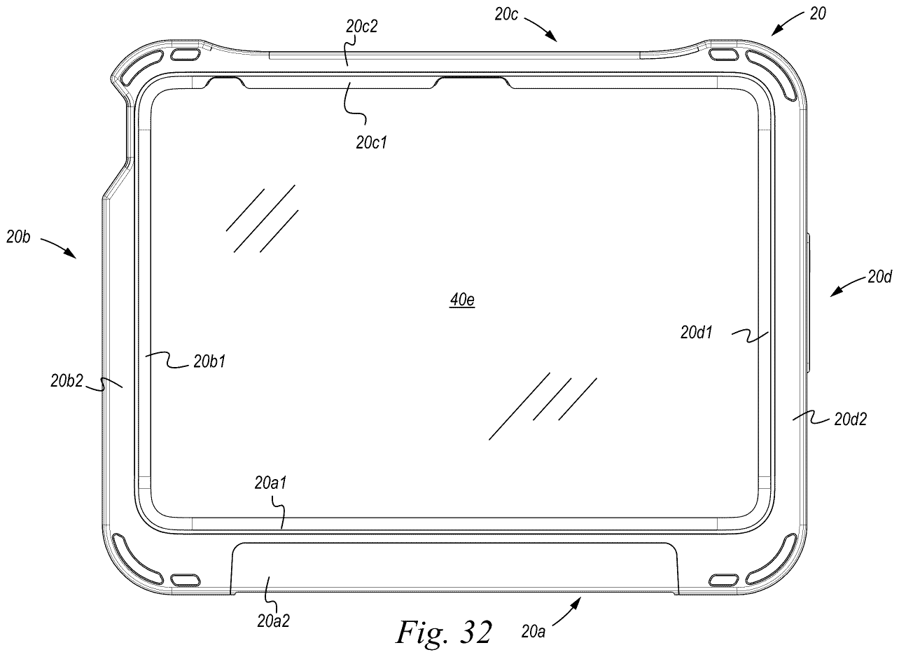

FIG. 32 is a front elevational view of the frame member of FIG. 9 coupled with the sheet member of FIG. 21.

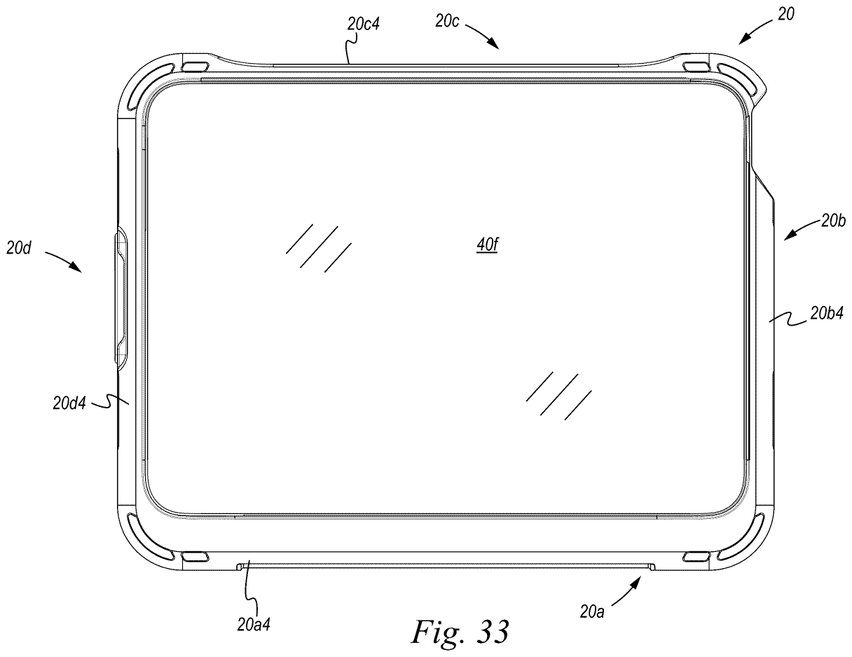

FIG. 33 is a rear elevational view of the frame member of FIG. 9 coupled with the sheet member of FIG. 21.

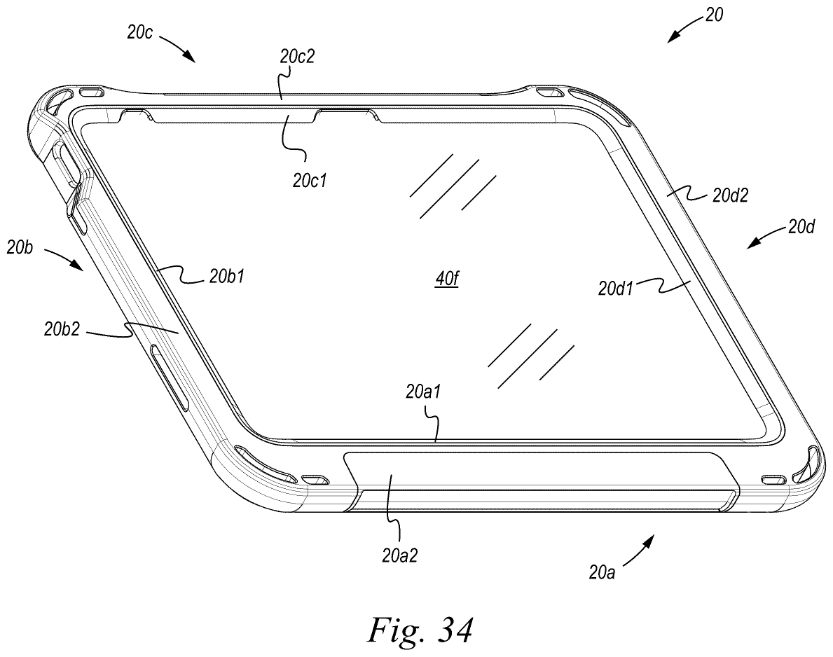

FIG. 34 is a back-right-top isometric view of the frame member of FIG. 9 coupled with the sheet member of FIG. 21.

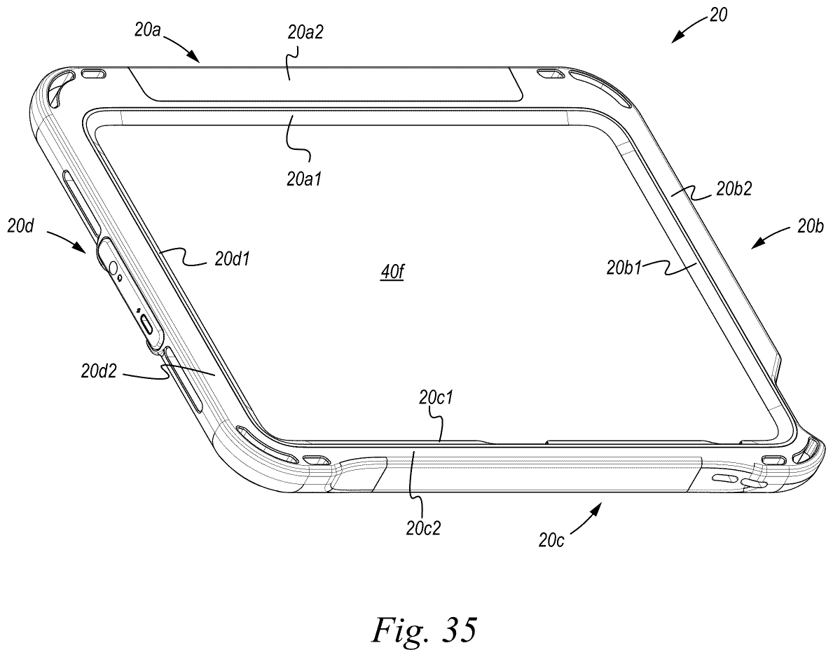

FIG. 35 is a front-left-top isometric view of the frame member of FIG. 9 coupled with the sheet member of FIG. 21.

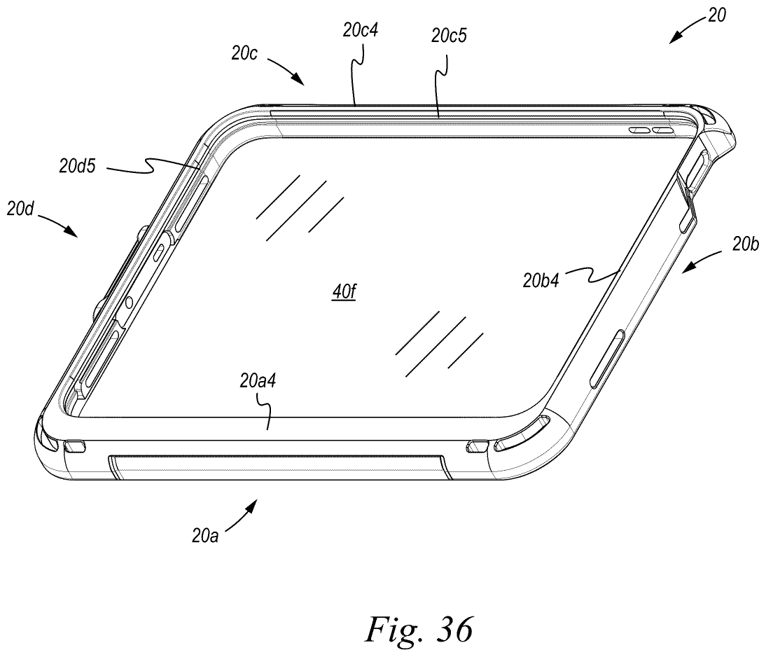

FIG. 36 is a back-left-top isometric view of the frame member of FIG. 9 coupled with the sheet member of FIG. 21.

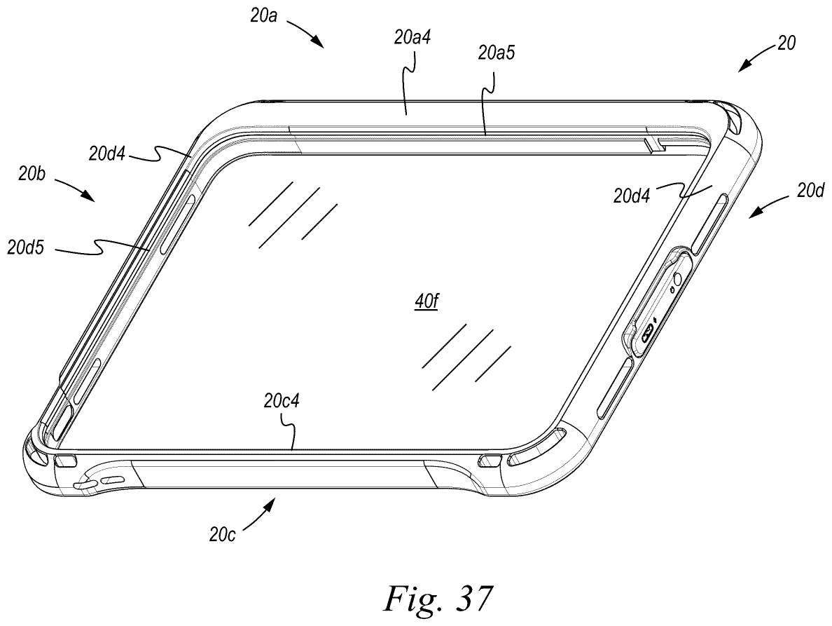

FIG. 37 is a front-right-bottom isometric view of the frame member of FIG. 9 coupled with the sheet member of FIG. 21.

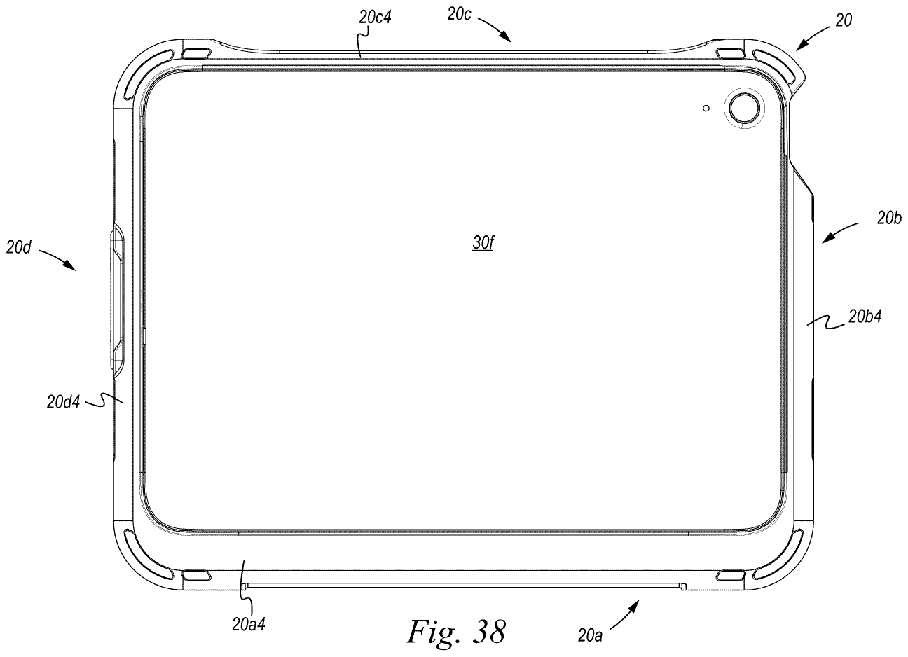

FIG. 38 is a rear elevational view of the frame member of FIG. 9 coupled with the portable electronic device of FIG. 15 and the sheet member of FIG. 21.

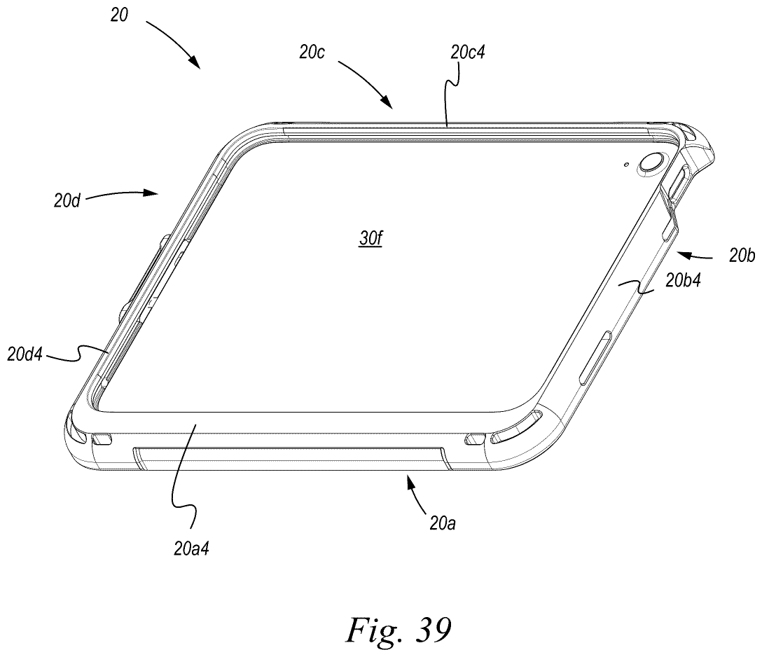

FIG. 39 is a back-left-top isometric view of the frame member of FIG. 9 coupled with the portable electronic device of FIG. 15 and the sheet member of FIG. 21.

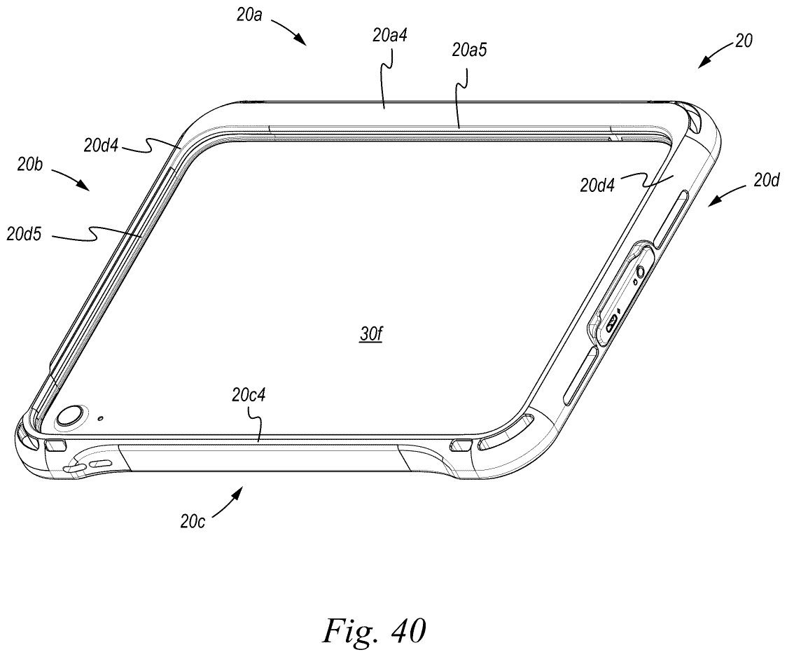

FIG. 40 is a front-right-bottom isometric view of the frame member of FIG. 9 coupled with the portable electronic device of FIG. 15 and the sheet member of FIG. 21.

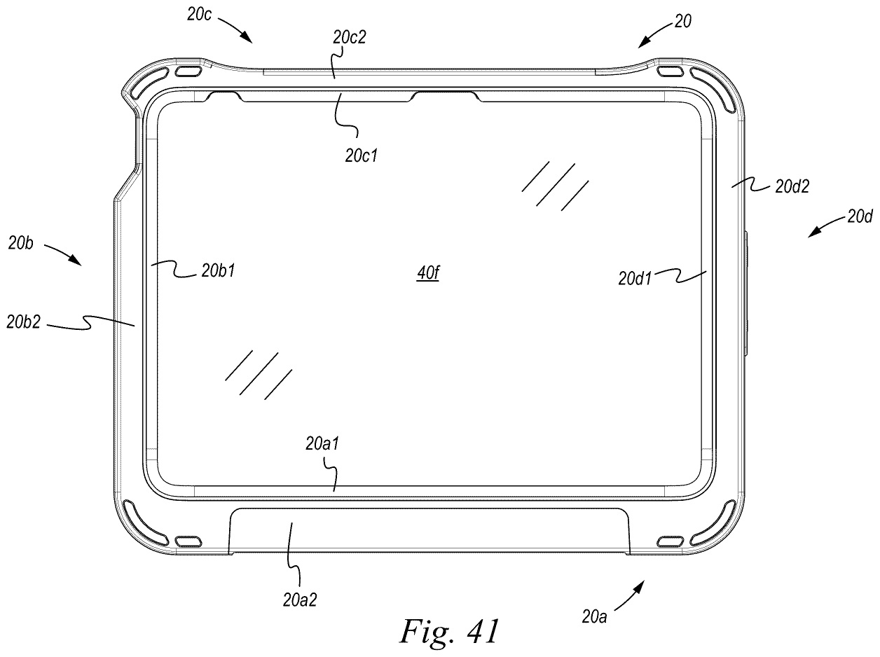

FIG. 41 is a front elevational view of the back member of FIG. 1 coupled with the frame member of FIG. 9, the portable electronic device of FIG. 15, and the sheet member of FIG. 21.

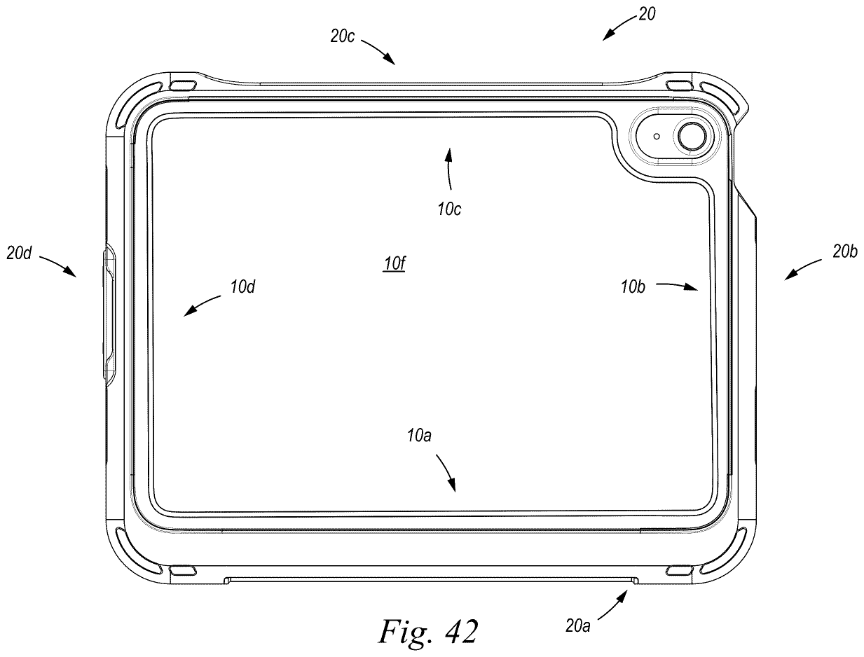

FIG. 42 is a rear elevational view of the back member of FIG. 1 coupled with the frame member of FIG. 9, the portable electronic device of FIG. 15, and the sheet member of FIG. 21.

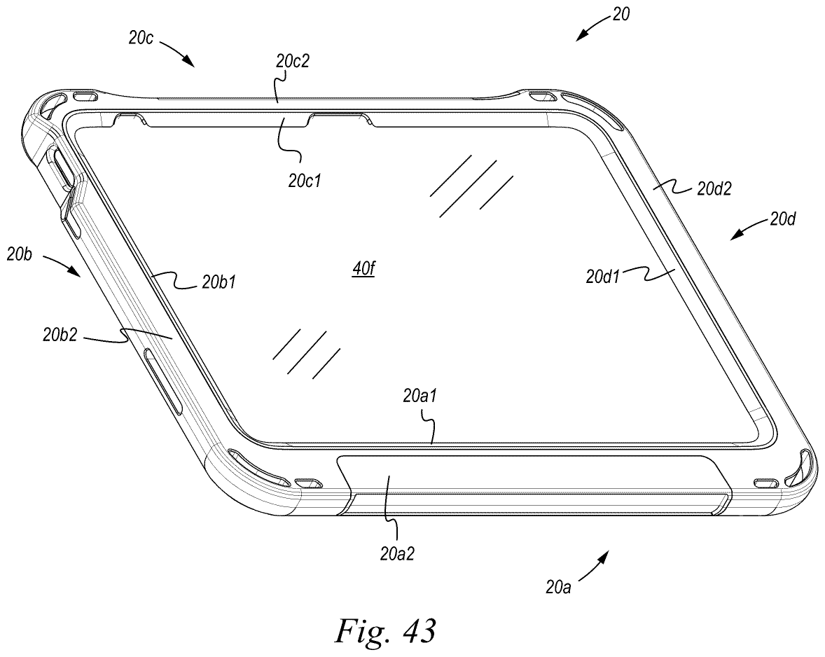

FIG. 43 is a back-right-top isometric view of the back member of FIG. 1 coupled with the frame member of FIG. 9, the portable electronic device of FIG. 15, and the sheet member of FIG. 21.

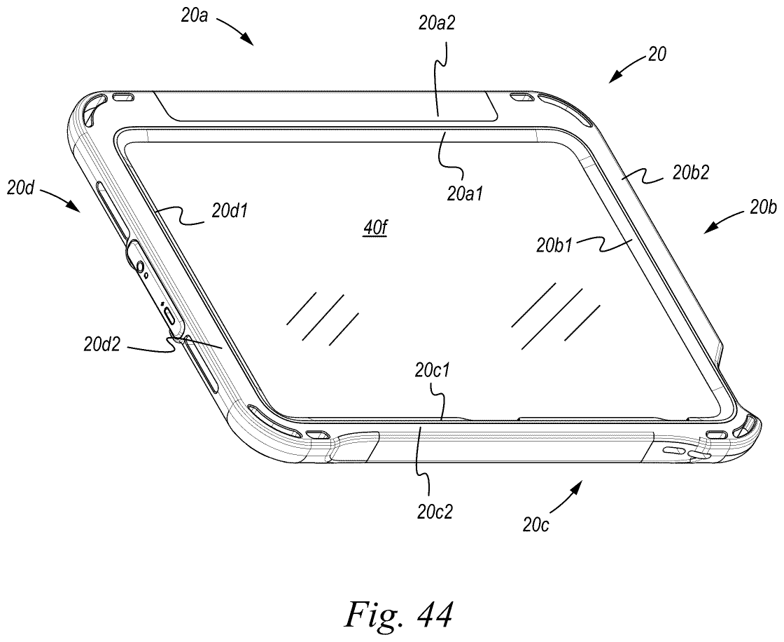

FIG. 44 is a front-left-top isometric view of the back member of FIG. 1 coupled with the frame member of FIG. 9, the portable electronic device of FIG. 15, and the sheet member of FIG. 21.

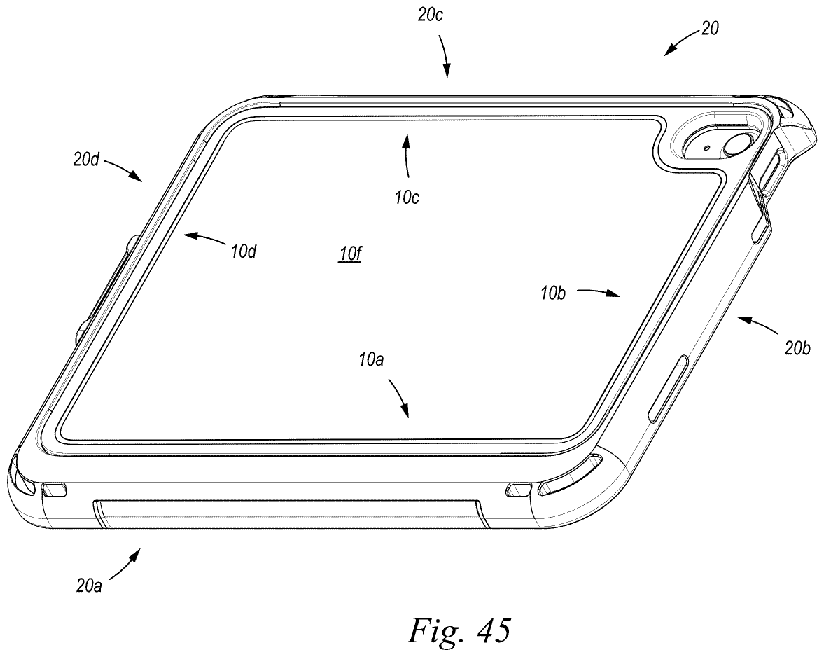

FIG. 45 is a back-left-top isometric view of the back member of FIG. 1 coupled with the frame member of FIG. 9, the portable electronic device of FIG. 15, and the sheet member of FIG. 21.

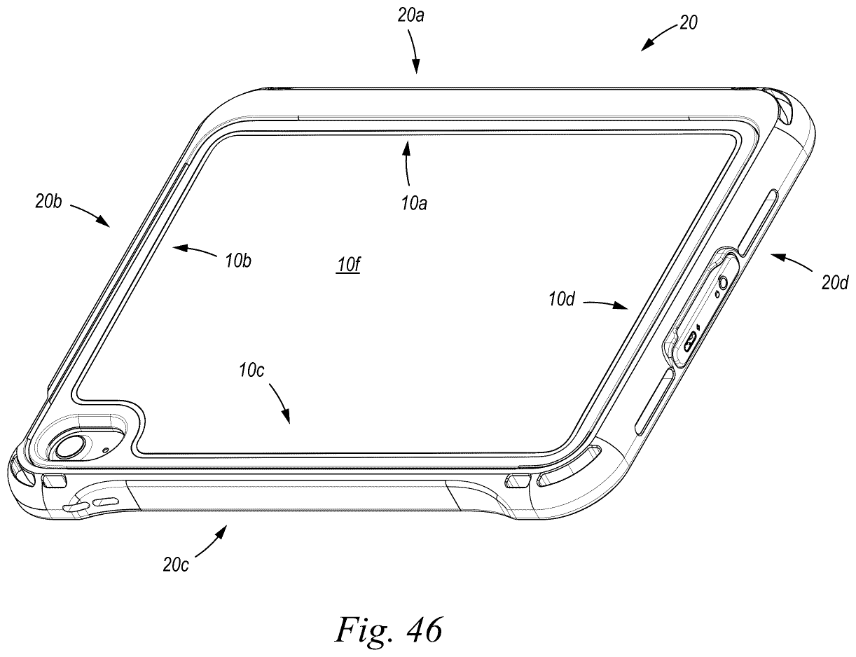

FIG. 46 is a front-right-bottom isometric view of the back member of FIG. 1 coupled with the frame member of FIG. 9, the portable electronic device of FIG. 15, and the sheet member of FIG. 21.

### DETAILED DESCRIPTION

In the following detailed description, reference is made to the accompanying drawings, which form a part hereof. In the drawings, similar symbols typically identify similar members, unless context dictates otherwise. The illustrative implementations described in the detailed description, drawings, and claims are not meant to be limiting.

Other implementations may be utilized, and other changes may be made, without departing from the spirit or scope of the subject matter presented here.

Turning to FIG. 1, depicted therein is a right-side elevational view of back member 10 illustrating the relative configuration of its structural portions. Back member 10 includes side portion 10a having base portion 10a1 and outwardly extending rib portion 10a2, side portion 10b having base portion 10b1 and rib portion 10b2, and side portion 10c having base portion 10c1 and rib portion 10c2. An interior surface portion 10e and an exterior surface portion 10f define opposing faces of back member 10, with each rib portion projecting outwardly from its respective base portion to engage corresponding groove portions of a frame member as later shown. The figure thus illustrates the peripheral rib structure and planar body arrangement of the back member used in the case system.

Turning to FIG. 2, depicted therein is a top plan view of back member 10 showing its arrangement of peripheral side portions and surface relationships. Back member 10 includes side portion 10d having base portion 10d1 and outwardly extending rib portion 10d2, along with adjacent side portions 10a and 10b respectively having base portions 10a1 and 10b1 and corresponding rib portions 10a2 and 10b2. Interior surface portion 10e and exterior surface portion 10f are shown extending between the peripheral side portions, illustrating the planar body structure of the back member and the uniform projection of the rib portions for coupling engagement with groove portions of a corresponding frame member as later shown.

Turning to FIG. 3, depicted therein is a front elevational view of back member 10. In certain embodiments, rib portions 10a2-10d2 may extend continuously along adjacent side portions, such as between side portions 10a and 10b or between 10c and 10d, forming a single uninterrupted rib corner structure that strengthens the coupling between back member 10 and a frame member later shown. As illustrated in FIGS. 1-3, back member 10 is substantially rectangular in plan view, with four generally straight side portions 10a-10d joined by rounded corner transitions to define a shape conforming to that of portable electronic device 30.

Turning to FIG. 4, depicted therein is a rear elevational view of back member 10.

Turning to FIG. 5, depicted therein is a front-left-top isometric view of back member 10.

Turning to FIG. 6, depicted therein is a front-right-top isometric view of back member 10.

Turning to FIG. 7, depicted therein is a back-left-top isometric view of back member 10.

Turning to FIG. 8, depicted therein is a back-right-bottom isometric view of back member 10.

Turning to FIG. 9, depicted therein is a front elevational view of frame member 20 showing the structure surrounding central opening 20e. Frame member 20 includes side portions 20a, 20b, 20c, and 20d, each having a corresponding ledge exterior surface portion 20a1, 20b1, 20c1, and 20d1, and a corresponding front perimeter body portion 20a2, 20b2, 20c2, and 20d2. Central opening 20e is defined within the interior region of frame member 20 and is peripherally bounded by the adjoining perimeter body portions, which together provide a continuous structure configured to receive a transparent sheet and align with a back member later shown. Each ledge portion 20a1-20d1 includes an inward-facing support surface configured to contact interior surface 40e of sheet member 40, thereby providing a stable seating region that defines the planar position of sheet 40 relative to central opening 20e.

Turning to FIG. 10, depicted therein is a rear elevational view of frame member 20 showing the inward-facing ledge and rear perimeter geometry. Frame member 20 includes side portions 20a, 20b, 20c, and 20d, each having corresponding ledge interior surface portions 20a3, 20b3, 20c3, and 20d3, and rear perimeter body portions 20a4, 20b4, 20c4, and 20d4. The ledge interior surface portions collectively define an inwardly extending support structure around central opening 20e, configured to receive and support a transparent sheet later shown when coupled with the back member.

Turning to FIG. 11, depicted therein is a front-right-top isometric view of frame member 20 including groove portion 20c5 extending along side portion 20c and groove portion 20d5 extending along side portion 20d. Groove portions 20c5 and 20d5 are positioned adjacent to ledge exterior surface portions 20c1 and 20d2 and front perimeter body portions 20c2 and 20d2, and are configured to receive rib portions 10c2 and 10d2 of back member 10 shown in earlier figures.

Turning to FIG. 12, depicted therein is a front-left-top isometric view of frame member 20 including groove portion 20a5 extending along side portion 20a and groove portion 20b5 extending along side portion 20b. Groove portions 20a5 and 20b5 are positioned adjacent to ledge exterior surface portions 20a1 and 20b1 and front perimeter body portions 20a2 and 20b2, and are configured to receive rib portions 10a2 and 10b2 of back member 10 shown in earlier figures.

In implementations, each groove portion 20a5-20d5 of frame member 20 faces inwardly toward central opening 20e and is shaped to receive the corresponding rib portion 10a2-10d2 of back member 10. The grooves and ribs interlock along the inner periphery so that insertion of back member 10 into frame 20 secures the two members in axial alignment relative to central opening 20e. Groove portions 20a5-20d5 may be joined at the corner transitions of frame 20 to define a continuous circumferential groove that follows the entire periphery of central opening 20e, enabling uniform engagement and sealing with the rib portions 10a2-10d2 of back member 10.

In implementations, back member 10 is composed of a rigid or semi-rigid polycarbonate material to provide structural support, whereas frame member 20 is composed of a thermoplastic polyurethane (TPU) material to provide flexibility and impact absorption during assembly and use. Frame 20 may be fabricated from an elastomeric material enabling temporary radial deformation of perimeter body portions 20a2-20d2 so that rib portions 10a2-10d2 of back member 10 may snap into corresponding groove portions 20a5-20d5 and lock securely upon release of the frame. Each side portion 10a-10d of back member 10 includes a corresponding rib portion 10a2-10d2 that mates with a respective groove portion 20a5-20d5 of frame 20, producing four discrete side-to-side coupling interfaces that collectively secure back member 10 to frame 20 around the full perimeter of central opening 20e.

Turning to FIG. 13, depicted therein is a back-left-top isometric view of frame member 20.

Turning to FIG. 14, depicted therein is a front-right-bottom isometric view of frame member 20.

Turning to FIG. 15, depicted therein is a front elevational view of portable electronic device 30 including side portion 30a, side portion 30b, side portion 30c, side portion 30d, and display portion 30e. Display portion 30e is positioned to align with central opening 20e of frame member 20 when portable electronic device 30 is coupled with back member 10 and frame member 20.

Turning to FIG. 16, depicted therein is a rear elevational view of portable electronic device 30 including rear surface portion 30f, which is positioned adjacent to interior surface portion 10e of back member 10 when portable electronic device 30 is coupled with back member 10 and frame member 20.

Turning to FIG. 17, depicted therein is a front-right-top isometric view of portable electronic device 30.

Turning to FIG. 18, depicted therein is a front-left-top isometric view of portable electronic device 30.

Turning to FIG. 19, depicted therein is a back-left-top isometric view of portable electronic device 30.

Turning to FIG. 20, depicted therein is a front-right-bottom isometric view of portable electronic device 30.

Turning to FIG. 21, depicted therein is a front elevational view of sheet member 40 including side portion 40a, side portion 40b, side portion 40c, side portion 40d, and interior surface portion 40e. Sheet member 40 is sized to correspond with central opening 20e of frame member 20, with side portions 40a through 40d positioned adjacent to ledge portions 20a1, 20b1, 20c1, and 20d1 of frame member 20 when assembled with back member 10 and portable electronic device 30.

Turning to FIG. 22, depicted therein is a rear elevational view of sheet member 40 including exterior surface portion 40f. When assembled, exterior surface portion 40f faces outwardly from frame member 20, opposite interior surface portion 40e, which is positioned adjacent to ledge portions 20a1, 20b1, 20c1, and 20d1 of frame member 20. The transparent sheet 40 may be removably retained against ledge portions 20a1-20d1 through an interference fit or a resilient lip formed along the inner edges of the perimeter body portions 20a2-20d2, allowing sheet 40 to be replaced or cleaned without removal of back member 10 from frame 20. When assembled, side portions 40a-40d of transparent sheet 40 are each positioned adjacent to ledge portions 20a1-20d1 of frame 20, thereby distributing contact forces evenly along interior surface 40e and maintaining uniform spacing between sheet 40 and back member 10.

Turning to FIG. 23, depicted therein is a back-right-top isometric view of sheet member 40.

Turning to FIG. 24, depicted therein is a back-left-top isometric view of sheet member 40.

Turning to FIG. 25, depicted therein is a right side elevational view of back member 10 coupled with portable electronic device 30.

Turning to FIG. 26, depicted therein is a top plan view of back member 10 coupled with portable electronic device 30.

Turning to FIG. 27, depicted therein is a front elevational view of back member 10 coupled with portable electronic device 30.

Turning to FIG. 28, depicted therein is a back-right-top isometric view of back member 10 coupled with portable electronic device 30.

Turning to FIG. 29, depicted therein is a front-left-top isometric view of back member 10 coupled with portable electronic device 30.

Turning to FIG. 30, depicted therein is a back-left-top isometric view of back member 10 coupled with portable electronic device 30.

Turning to FIG. 31, depicted therein is a front-right-bottom isometric view of back member 10 coupled with portable electronic device 30.

Turning to FIG. 32, depicted therein is a front elevational view of frame member 20 coupled with sheet member 40.

Turning to FIG. 33, depicted therein is a rear elevational view of frame member 20 coupled with sheet member 40.

Turning to FIG. 34, depicted therein is a back-right-top isometric view of frame member 20 coupled with sheet member 40.

Turning to FIG. 35, depicted therein is a front-left-top isometric view of frame member 20 coupled with sheet member 40.

Turning to FIG. 36, depicted therein is a back-left-top isometric view of frame member 20 coupled with sheet member 40.

Turning to FIG. 37, depicted therein is a front-right-bottom isometric view of frame member 20 coupled with sheet member 40.

Turning to FIG. 38, depicted therein is a rear elevational view of frame member 20 coupled with portable electronic device 30 and sheet member 40.

Turning to FIG. 39, depicted therein is a back-left-top isometric view of frame member 20 coupled with portable electronic device 30 and sheet member 40.

Turning to FIG. 40, depicted therein is a front-right-bottom isometric view of frame member 20 coupled with portable electronic device 30 and sheet member 40.

Turning to FIG. 41, depicted therein is a front elevational view of back member 10 coupled with frame member 20, portable electronic device 30, and sheet member 40.

Turning to FIG. 42, depicted therein is a rear elevational view of back member 10 coupled with frame member 20, portable electronic device 30, and sheet member 40.

Turning to FIG. 43, depicted therein is a back-right-top isometric view of back member 10 coupled with frame member 20, portable electronic device 30, and sheet member 40.

Turning to FIG. 44, depicted therein is a front-left-top isometric view of back member 10 coupled with frame member 20, portable electronic device 30, and sheet member 40.

Turning to FIG. 45, depicted therein is a back-left-top isometric view of back member 10 coupled with frame member 20, portable electronic device 30, and sheet member 40.

Turning to FIG. 46, depicted therein is a front-right-bottom isometric view of back member 10 coupled with frame member 20, portable electronic device 30, and sheet member 40.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

What is claimed is:

1. A case system for a portable electronic device, the case system comprising:
(I) a back member including:
(A) an exterior surface portion,
(B) an interior surface portion, and
(C) at least one side portion including at least one rib portion extending outwardly; and
(II) a frame member including:
(A) a central opening having a periphery,
(B) at least one perimeter body portion peripherally bounding at least a portion of the periphery of the central opening and including at least one groove portion facing the central opening, wherein the at least one groove portion is coupled with the at least one rib portion of the back member, and
(C) at least one ledge portion extending inwardly from the at least one perimeter body portion into the central opening.

2. The case system of claim 1,
wherein the back member includes a plurality of side portions and a plurality of rib portions respectively extending from the plurality of side portions.

3. The case system of claim 2,
wherein at least one of the plurality of rib portions extends continuously along at least two adjacent side portions of the back member.

4. The case system of claim 1,
wherein the frame member includes a plurality of perimeter body portions, and
wherein the at least one groove portion includes a plurality of groove portions respectively extending along the plurality of perimeter body portions.

5. The case system of claim 4,
wherein the plurality of groove portions collectively form a continuous groove extending along at least a portion of the periphery of the central opening.

6. The case system of claim 1, further including at least one transparent sheet portion positioned adjacent to the at least one ledge portion,
wherein the interior surface portion of the back member is positioned adjacent to the portable electronic device when the case system is coupled with the portable electronic device, and
wherein the at least one transparent sheet portion is removably retained on the at least one ledge portion.

7. The case system of claim 6,
wherein the at least one transparent sheet portion is retained on the at least one ledge portion by at least one of an interference fit and a resilient lip formed along an inner edge of the at least one perimeter body portion.

8. A case system for a portable electronic device, the case system comprising:
(I) a back member including:
(A) an interior surface portion, and
(B) at least one side portion; and
(II) a frame member including:
(A) a central opening with a periphery sized to receive the portable electronic device when the case system is coupled with the portable electronic device, and
(B) at least one perimeter body portion peripherally bounding at least a portion of the periphery of the central opening,
wherein the at least one perimeter body portion of the frame member is couplable with the at least one side portion of the back member.

9. The case system of claim 8,
wherein the at least one perimeter body portion includes an inwardly facing circumferential groove defined as a continuous channel within inner surfaces of the at least one perimeter body portion.

10. The case system of claim 9,
wherein the at least one rib portion of the back member is couplable with the circumferential groove of the frame member, and
wherein the frame member is flexibly deformable to allow the at least one rib portion to snap into the circumferential groove.

11. The case system of claim 9,
wherein the back member includes at least one polycarbonate material, and
wherein the frame member includes at least one thermoplastic polyurethane material.

12. The case system of claim 8,
further comprising at least one rib portion extending from the back member,
wherein the back member includes four side portions and the at least one rib portion extends continuously along at least two adjacent side portions.

13. The case system of claim 8, further including a transparent sheet sized to cover the central opening of the frame member when positioned adjacent the at least one perimeter body portion of the frame member,
wherein the frame member further includes at least one ledge portion extending inwardly from the at least one perimeter body portion, and
wherein the transparent sheet is planar and lies in contact with an inward-facing surface of the at least one ledge portion.

14. The case system of claim 13,
wherein the transparent sheet is removably attachable to the frame member independently of the back member.

15. (canceled)

16. (canceled)

17. (canceled)

18. (canceled)

19. (canceled)

20. (canceled)

21. A case system for a portable electronic device, the case system comprising:
(I) a back member including:
(A) an interior surface portion,
(B) an exterior surface portion opposite the interior surface portion, and
(C) at least one side portion including at least one rib portion extending outwardly from the at least one side portion;
(II) a frame member including:
(A) a central opening having a periphery,
(B) at least one perimeter body portion peripherally bounding at least a portion of the periphery of the central opening,
(C) at least one groove portion included in the at least one perimeter body portion and facing the central opening, wherein the at least one groove portion is coupled with the at least one rib portion of the back member, and
(D) at least one ledge portion extending inwardly from the at least one perimeter body portion into the central opening; and
(III) a transparent sheet,
wherein the transparent sheet is positioned adjacent to the at least one ledge portion,
wherein the at least one groove portion and the at least one rib portion secure the back member to the frame member, and
wherein the interior surface portion of the back member is positioned adjacent to a rear surface portion of the portable electronic device when the case system is coupled with the portable electronic device.

22. The case system of claim 21,
wherein the back member includes at least two adjacent side portions, and
wherein the at least one rib portion extends continuously along the at least two adjacent side portions.

23. The case system of claim 21,
wherein the at least one groove portion forms a continuous groove extending along at least a portion of the periphery of the central opening.

24. The case system of claim 21,
wherein the at least one ledge portion includes an inward-facing support surface contacting an interior surface portion of the transparent sheet.

25. The case system of claim 21,
wherein the transparent sheet is removably retained adjacent to the at least one ledge portion by at least one of an interference fit and a resilient lip formed along an inner edge of the at least one perimeter body portion.

26. The case system of claim 21,
wherein the back member includes at least one polycarbonate material, and
wherein the frame member includes at least one thermoplastic polyurethane material.
